(19) United States
(12) Patent Application Publication
(10) Pub. No.: US 2010/0207209 A1
(43) Pub. Date: Aug. 19, 2010

(54) SEMICONDUCTOR DEVICE AND PRODUCING METHOD THEREOF

(76) Inventor: Hideki Inokuma, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/563,298

(22) Filed: Sep. 21, 2009

(30) Foreign Application Priority Data
Feb. 17, 2009 (JP) 2009-33945

(51) Int. Cl. H01L 29/786; H01L 21/336

(52) U.S. Cl. 257/347; 438/151; 257/E29.273; 257/E21.415

(57) ABSTRACT

A semiconductor device having a small parasitic resistance and a high driving current is provided. The semiconductor device includes a fin portion that includes a pair of source/drain regions located on both end sides and a channel region sandwiched between the pair of source/drain regions; films that are formed on both sides in a channel-width direction of the fin portion; a gate electrode that is provided so as to stride across the channel region of the fin portion; a gate insulating film that is interposed between the gate electrode and the channel region; and a stress applying layer that applies a stress to the channel region of the fin portion, an upper surface and side surfaces of the source/drain region being coated with the stress applying layer in the fin portion, a lower end surface of the stress applying layer being in contact with the film with no gap.

### CROSS REFERENCE TO RELATED APPLICATIONS

This application is based upon and claims benefit of priority from prior Japanese Patent Application No. 2009-33945, filed on Feb. 17, 2009, the entire contents of which are incorporated herein by reference.

### BACKGROUND OF THE INVENTION

1. Field of the Invention

The present invention relates to a semiconductor device and a producing method thereof, particularly to a FinFET to which a strained silicon technique is applied and a producing method thereof.

2. Background Art

Recently the influence of various parasitic effects such as a parasitic resistance, a parasitic capacitance, and a short channel effect is growing with the progress of integration of the semiconductor device. A Fin Field Effect Transistor (hereinafter also referred to as FinFET) is actively developed in order to realize the semiconductor device that can suppress the parasitic effects (for example, see Japanese Patent Application Laid-Open No. 2005-294789).

### SUMMARY OF THE INVENTION

According to a first aspect of the invention, a semiconductor device includes a fin portion that includes a pair of source/drain regions located on both end sides and a channel region sandwiched between the pair of source/drain regions;

films that are formed on both sides in a channel-width direction of the fin portion; a gate electrode that is provided so as to stride across the channel region of the fin portion; a gate insulating film that is interposed between the gate electrode and the channel region; and a stress applying layer that applies a stress to the channel region of the fin portion, an upper surface and side surfaces of the source/drain region being coated with the stress applying layer in the fin portion, a lower end surface of the stress applying layer being in contact with the film with no gap.

According to a second aspect of the invention, a semiconductor device producing method includes preparing a silicon substrate; depositing sequentially a first mask material and a second mask material on the silicon substrate; patterning the first mask material and the second mask material; forming a substrate main body and a fin portion by etching the silicon substrate from a surface to a predetermined depth with the patterned second mask material as a mask, the fin portion being formed on the substrate main body while formed integrally with the substrate main body, the fin portion including a pair of source/drain regions located on both end sides and a channel region sandwiched between the pair of source/drain regions; depositing silicon oxide on the substrate main body, the fin portion, and the second mask material; forming an element isolation insulating film on the substrate main body by etching the silicon oxide to a predetermined thickness with the second mask material as a mask; depositing a silicon nitride film or silicon carbide nitride film on the element isolation insulating film, the fin portion, and the second mask material; forming a film on the element isolation insulating film by etching the silicon nitride or the silicon carbide nitride film to a predetermined thickness with the first mask material as a mask; forming a gate insulating film on the fin portion; forming a gate electrode that sandwiches the channel region of the fin portion, the gate insulating film being interposed between the gate electrode and the channel region; and forming a stress applying layer such that an upper surface and both side surfaces of the source/drain region of the fin portion are coated with the stress applying layer, the stress applying layer being in contact with the film with no gap, the stress applying layer being made of silicon germanium or silicon carbide.

### BRIEF DESCRIPTION OF THE DRAWINGS

FIG. 1A is a perspective view illustrating FinFET according to a first embodiment of the invention;

FIG. 1B is a top view illustrating FinFET of the first embodiment;

FIG. 1C is a sectional view taken along a line A-A′ of FIG. 1B;

FIG. 2A is a sectional view illustrating a process for producing FinFET of the first embodiment;

FIG. 2B is a sectional view following FIG. 2A illustrating the process for producing FinFET of the first embodiment;

FIG. 2C is a sectional view following FIG. 2B illustrating the process for producing FinFET of the first embodiment;

FIG. 2D is a sectional view following FIG. 2C illustrating the process for producing FinFET of the first embodiment;

FIG. 2E is a sectional view following FIG. 2D illustrating the process for producing FinFET of the first embodiment;

FIG. 2F is a sectional view following FIG. 2E illustrating the process for producing FinFET of the first embodiment;

FIG. 2G is a sectional view following FIG. 2F illustrating the process for producing FinFET of the first embodiment;

FIG. 2H is a sectional view following FIG. 2G illustrating the process for producing FinFET of the first embodiment;

FIG. 3A is a perspective view illustrating FinFET according to a second embodiment of the invention;

FIG. 3B is a top view illustrating FinFET of the second embodiment;

FIG. 3C is a sectional view taken along a line A-A′ of FIG. 3B;

FIG. 4A is a sectional view illustrating a process for producing FinFET of the second embodiment;

FIG. 4B is a sectional view following FIG. 4A illustrating the process for producing FinFET of the second embodiment;

FIG. 4C is a sectional view following FIG. 4B illustrating the process for producing FinFET of the second embodiment;

FIG. 4D is a sectional view following FIG. 4C illustrating the process for producing FinFET of the second embodiment;

FIG. 4E is a sectional view following FIG. 4D illustrating the process for producing FinFET of the second embodiment;

FIG. 5A is a perspective view illustrating FinFET according to a comparative example;

FIG. 5B is a top view illustrating FinFET of the comparative example; and

FIG. 5C is a sectional view taken along a line A-A′ of FIG. 5B.

### DETAILED DESCRIPTION OF THE EMBODIMENTS

A background in which the inventor made the present invention will be described before embodiments of the invention are described.

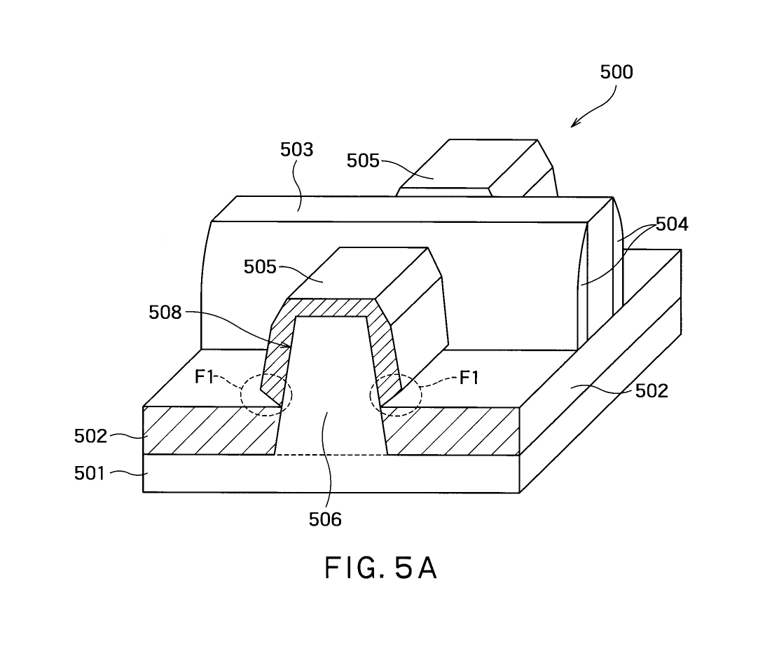

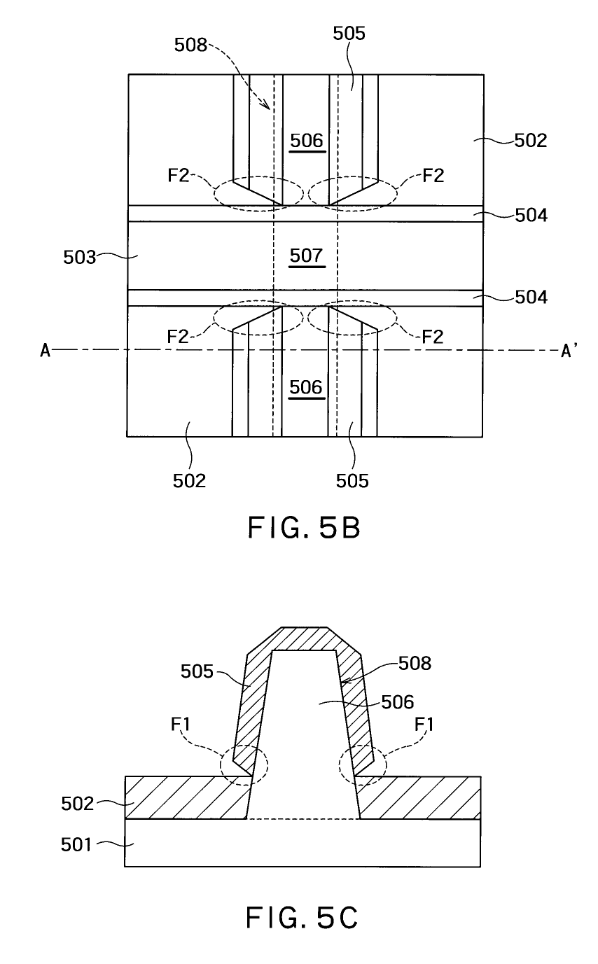

A configuration of FinFET 500 according to a comparative example will be described with reference to FIGS. 5A to 5C. FIG. 5A is a perspective view illustrating FinFET 500 of the comparative example, FIG. 5B is a top view of FinFET 500, and FIG. 5C is a sectional view taken along a line A-A′ of FIG. 5B.

Referring to FIG. 5A, FinFET 500 includes a fin 508, a gate electrode 503, sidewalls 504, a stress applying layer 505, and a gate insulating film (not illustrated). FinFET 500 is insulated from an adjacent semiconductor element by an element isolation insulating film (SiO₂) 502.

The fin 508 is formed on a semiconductor substrate main body 501 while formed integrally with the semiconductor substrate main body 501. As illustrated in FIG. 5B, the fin 508 includes source/drain regions 506 and a channel region 507 that is sandwiched between the source/drain regions 506.

The gate insulating film is formed on the fin 508 of the channel region 507.

As illustrated in FIG. 5A, the gate electrode 503 is disposed so as to stride across the channel region 507. The gate electrode 503 sandwiches the channel region 507 with the gate insulating film interposed therebetween.

The sidewalls 504 are formed on both side surfaces of the gate electrode 503. For example, the sidewall 504 is made of silicon nitride (Si₃N₄).

As illustrated in FIGS. 5A to 5C, the stress applying layer 505 is formed such that, in the fin 508, an upper surface of the source/drain region 506 and both side surfaces along a channel direction are covered therewith. The stress applying layer 505 is a semiconductor crystal layer that is formed on the source/drain region 506 by selective growth. A lattice constant of the semiconductor crystal layer is selected so as to be different from a lattice constant of a semiconductor crystal used for the source/drain region 506. The different lattice constants apply a stress to the channel region 507 to generate a strain, which allows carrier mobility to be improved.

For example, silicon germanium (SiGe) or silicon carbide (SiC) can be cited as a material for the stress applying layer 505 having the lattice constant different from that of silicon (Si) used for the fin 508. In the case of SiGe, because SiGe has the lattice constant larger than that of Si, a compressive stress is applied to the channel region 507 in a gate-length direction (channel direction). Therefore, the hole mobility can be enhanced. On the other hand, in the case of SiC, because SiC has the lattice constant smaller than that of Si, a tensile stress is applied to the channel region 507 in the gate-length direction (channel direction). Therefore, the electron mobility can be enhanced.

When the carrier mobility is enhanced, a driving current can be increased while a parasitic resistance of FinFET 500 is reduced.

The stress applied to the channel region 507 increases with increasing volume of the stress applying layer 505.

Accordingly, the stress can be increased to some extent by thickening the stress applying layer 505. However, because a size of FinFET is enlarged, there is a limitation from the viewpoint of integrating many FinFETs at high density.

Generally, the element isolation insulating film 502 is made of a silicon oxide (SiO₂) film. In such cases, as illustrated in FIGS. 5A to 5C, the inventor learned that a facet is generated when the stress applying layer 505 is selectively grown.

That is, as illustrated in FIGS. 5A and 5C, the facet is generated in a portion (portion F1) in which the source/drain region 506 is in contact with a surface of the element isolation insulating film 502.

As illustrated in FIG. 5B, the facet is also generated in a portion (portion F2) in which the source/drain region 506 is in contact with the sidewall 504. Although a mechanism by which the facet is generated is not completely explained at this moment, this is attributed to the following fact. That is, the crystal growth from a plane direction except for the facet is obstructed by the generation of the facet in the portion F1, and therefore the facet is generated in the portion F2.

When the facets are generated, as can be seen from FIGS. 5B and 5C, gaps are formed between the stress applying layer 505 and the element isolation insulating film 502 and between the stress applying layer 505 and the sidewall 504. The volume of the stress applying layer 505 is smaller than that of the case in which the gaps are not generated. A gap is formed between the stress applying layer 505 and the sidewall 104 by the facet generated in the portion F2, and the stress applied to the channel region 507 is largely decreased, which causes a problem in that the stress applying layer 505 insufficiently applies the stress to the channel region 507 to insufficiently improve the parasitic resistance and the driving current.

The inventor made the invention based on a unique technical knowledge. In the invention, the strain is sufficiently generated in the channel region by preventing the generation of the facet, whereby the driving current is increased while the parasitic resistance is reduced.

Exemplary embodiments of the invention will be described below with reference to the drawings. A component having an equivalent function is designated by the same numeral, and the detailed description will not be repeated.

### First Embodiment

A first embodiment of the invention will be described below. The first embodiment differs from the comparative example in that a film 109 is provided. The element isolation insulating film 102 is covered with the film 109 made of silicon nitride (Si₃N₄).

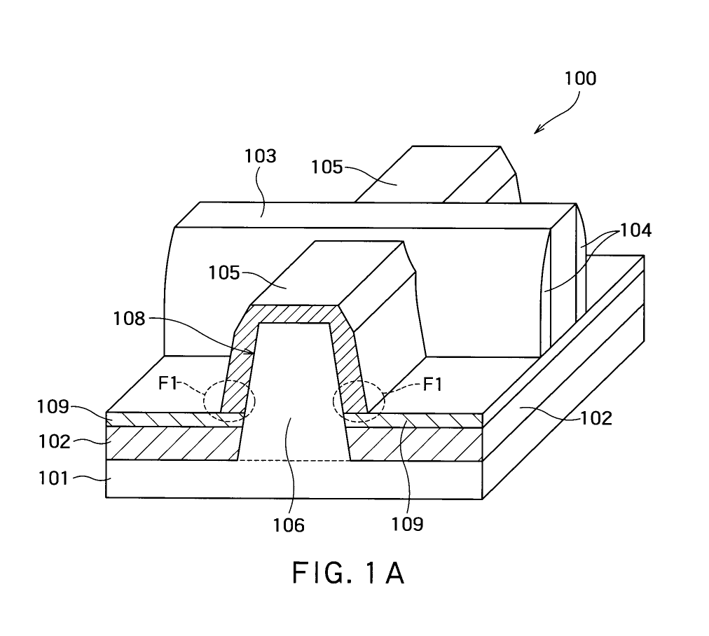

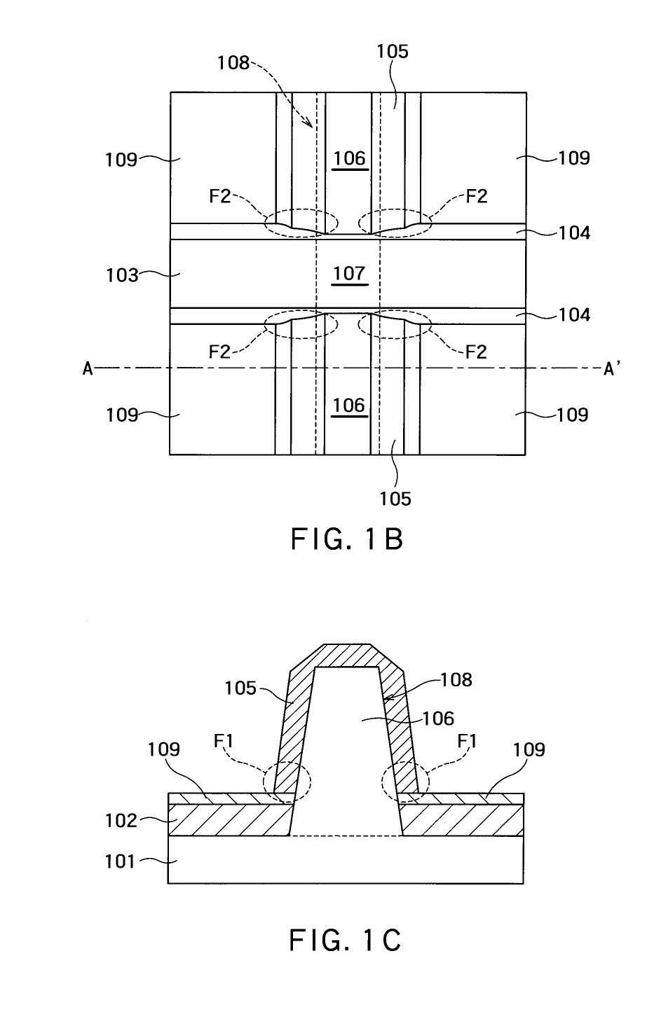

A configuration of FinFET 100 of the first embodiment will be described with reference to FIGS. 1A to 1C. FIG. 1A is a perspective view illustrating FinFET 100 of the first embodiment, FIG. 1B is a top view illustrating FinFET 100, and FIG. 1C is a sectional view taken along a line A-A′ of FIG. 1B.

Referring to FIG. 1A, FinFET 100 includes a fin 108, a gate electrode 103, sidewalls 104, a stress applying layer 105, and a gate insulating film (not illustrated). FinFET 100 is insulated from an adjacent semiconductor element by an element isolation insulating film (SiO₂) 102.

The fin 108 is formed on a semiconductor substrate main body 101 while formed integrally with the semiconductor substrate main body 101. As illustrated in FIG. 1B, the fin 108 includes source/drain regions 106 and a channel region 107 that is sandwiched between the source/drain regions 106.

The gate insulating film is formed on the fin 108 of the channel region 107.

As illustrated in FIG. 1A, the gate electrode 103 is disposed so as to stride across the channel region 107. The gate electrode 103 sandwiches the channel region 107 with the gate insulating film interposed therebetween.

The sidewalls 104 are formed on both side surfaces of the gate electrode 103. For example, the sidewall 104 is made of silicon nitride (Si₃N₄).

As illustrated in FIGS. 1A to 1C, the stress applying layer 105 is formed such that, in the fin 108, an upper surface of the source/drain region 106 and both side surfaces along a channel direction are covered therewith. For example, silicon germanium (SiGe) or silicon carbide (SiC) is used as a material for the stress applying layer 105. SiGe applies the compressive stress to the channel region 107 in the gate-length direction (channel direction) to enhance the hole mobility. Therefore, SiGe is suitable to a p-type FinFET. On the other hand, SiC applies the tensile stress to the channel region 107 in the gate-length direction (channel direction) to enhance the electron mobility. Therefore, SiC is suitable to an n-type FinFET.

As illustrated in FIGS. 1A to 1C, because the film 109 made of silicon nitride is formed on the element isolation insulating film 102, the facets are not generated in the portion F1 and the portion F2, and the stress applying layer 105 comes into contact with the film 109 and the sidewalls 104 with no gap, thereby preventing the decrease in volume of the stress applying layer 105. Because the gap is not formed between the stress applying layer 105 and the sidewall 104, the stress can efficiently be applied to the channel region 107. Therefore, the higher stress is applied to the channel region 107 to increase the carrier mobility, so that the parasitic resistance can be decreased while the driving current is increased.

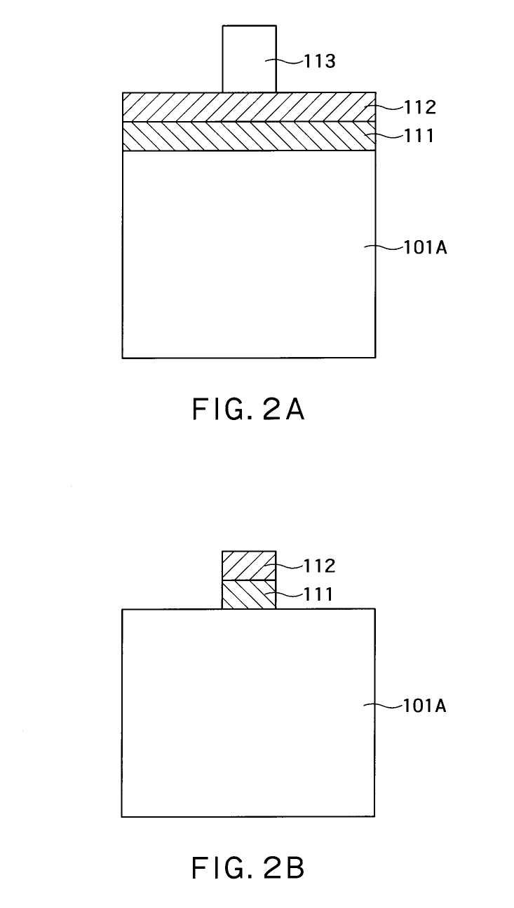

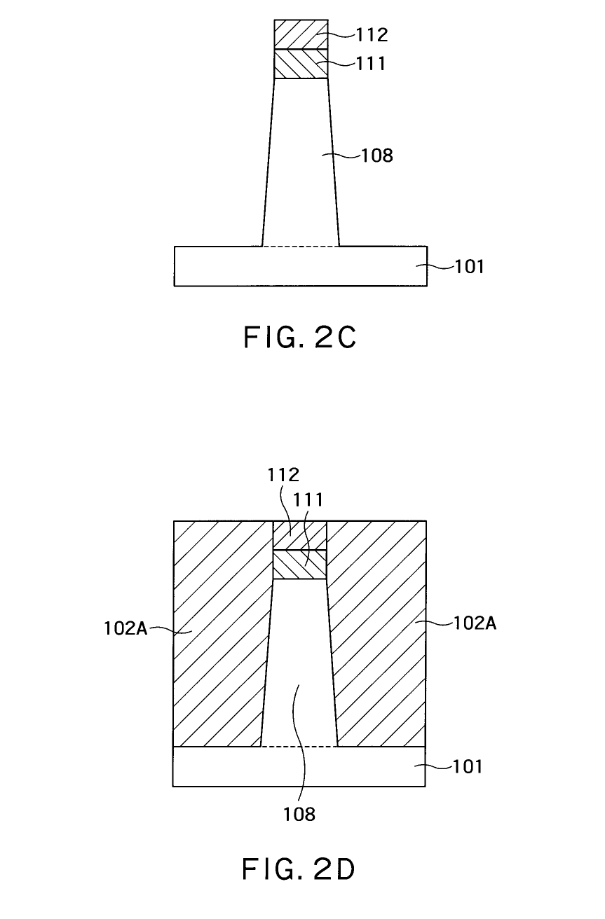

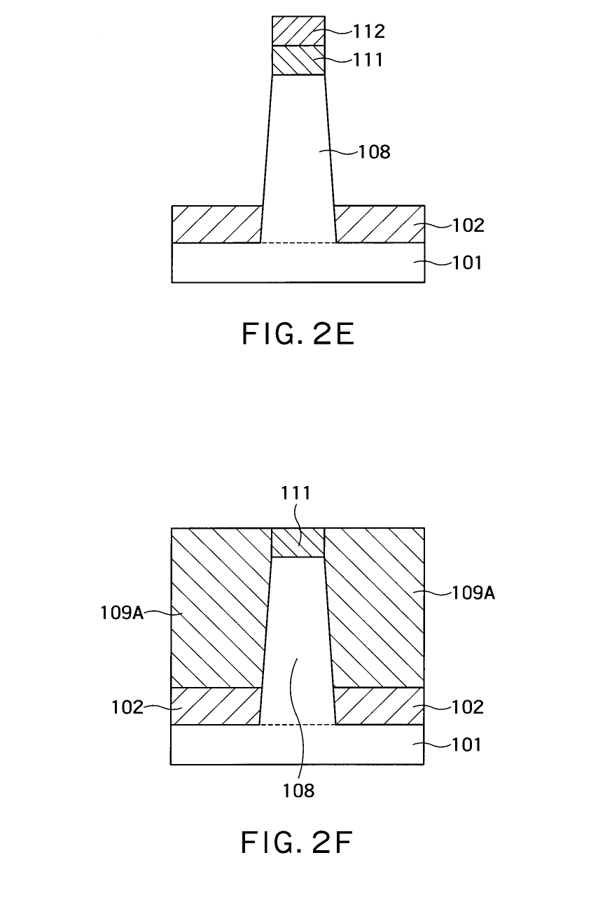

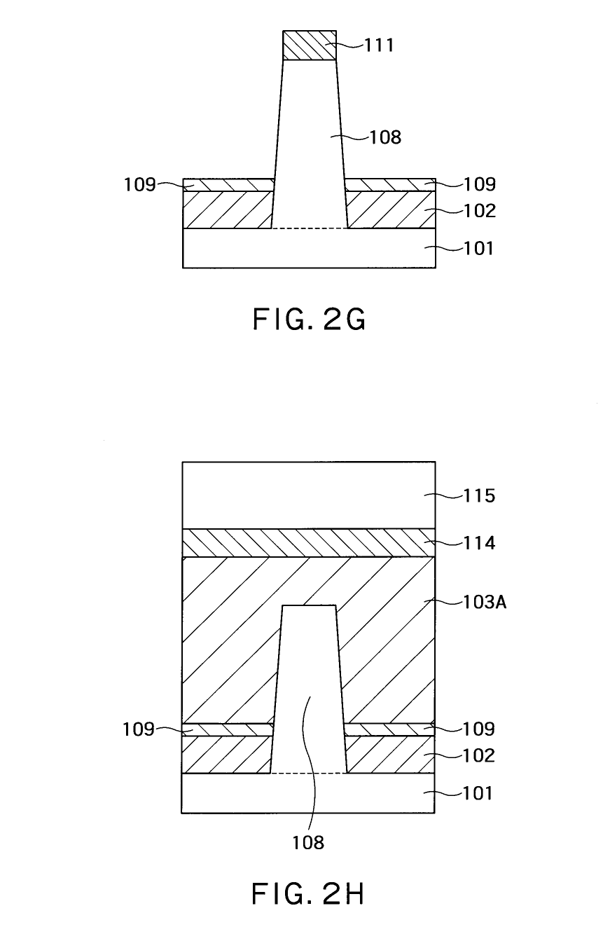

A method for producing FinFET 100 according to the first embodiment will be described with reference to FIGS. 2A to 2H.

(1) Referring to FIG. 2A, a first silicon oxide (SiO₂) film 111 and a first silicon nitride (Si₃N₄) film 112 are sequentially deposited as a mask material on a semiconductor substrate (Si substrate) 101A. Then, a photoresist is applied onto the first silicon nitride film 112 to form a photoresist film 113.

(2) Referring to FIG. 2A, a photoresist film 113 is patterned by photolithography based on a shape of the fin 108.

(3) Referring to FIG. 2B, the first silicon oxide film 111 and the first silicon nitride film 112 are processed by dry etching with the patterned photoresist film 113 as a mask.

(4) Referring to FIG. 2C, after the photoresist film 113 is removed, the semiconductor substrate 101A is etched to form the fin 108 with the first silicon nitride film 112 as the mask. The fin 108 is formed on the semiconductor substrate main body 101 while formed integrally with the semiconductor substrate main body 101. For example, the fin 108 has a height of 100 nm to 200 nm.

(5) Referring to FIG. 2D, a second silicon oxide film 102A is deposited on the semiconductor substrate main body 101, the fin 108, and the first silicon nitride film 112.

(6) Referring to FIG. 2D, the second silicon oxide film 102A is planarized by chemical mechanical polishing (CMP) with the first silicon nitride film 112 as a stopper.

(7) Referring to FIG. 2E, the second silicon oxide film 102A is retreated to form the element isolation insulating film 102 by the dry etching with the first silicon nitride film 112 as the mask. Preferably, the element isolation insulating film 102 is formed thinner by at least a thickness of the film 109 such that the volume of the stress applying layer 105 is not decreased by the film 109 formed in the subsequent process. For example, the element isolation insulating film 102 has the thickness of 20 nm to 30 nm.

(8) Referring to FIG. 2F, a second silicon nitride film 109A is deposited on the element isolation insulating film 102, the fin 108, and the first silicon nitride film 112.

(9) Referring to FIG. 2F, the second silicon nitride film 109A is planarized by CMP with the first silicon oxide film 111 as the stopper.

(10) Referring to FIG. 2G, the first silicon oxide film 111 is masked, the second silicon nitride film 109A is retreated by the dry etching to form the film 109 with which the element isolation insulating film 102 is covered. For example, the film 109 has the thickness of 10 nm. The sum of the thicknesses of the element isolation insulating film 102 and film 109 is substantially equal to the thickness of the element isolation insulating film 502 of the comparative example.

(11) After the first silicon oxide film 111 is removed, the gate insulating film (not illustrated) is deposited on the fin 108. Then, referring to FIG. 2H, polysilicon 103A is deposited on the gate insulating film and the film 109. Therefore, the fin 108 is buried in the polysilicon 103A.

(12) As illustrated in FIG. 2H, a third silicon nitride film 114 is deposited as a mask material on the polysilicon 103A.

(13) As illustrated in FIG. 2H, the photoresist is applied onto the third silicon nitride film 114 to form a photoresist film 115. Then, the photoresist film 115 is patterned by photolithography based on a shape of the gate electrode.

(14) The third silicon nitride film 114 is processed by the dry etching with the patterned photoresist film 115 as the mask.

(15) Then, after photoresist film 115 is removed, the polysilicon 103A is processed by the dry etching with the third silicon nitride film 114 as the mask, thereby forming the gate electrode 103. As illustrated in FIGS. 1A and 1B, the gate electrode 103 is formed so as to stride across the channel region 107 of the fin 108. The gate insulating film acts as an etching stopper in etching the polysilicon 103A.

(16) The gate insulating film deposited on the source/drain region 106 is removed by the etching.

(17) Then, ion injection is performed to the source/drain region 106, thereby forming an extension region (not illustrated).

(18) Then, a fourth silicon nitride film 104A (not illustrated) is deposited on the gate electrode 103, the source/drain region 106, and the film 109. Then, overall etching is performed to the fourth silicon nitride film 104A to form the sidewalls 104 (sidewall spacers) on both the side surfaces of the gate electrode 103. The sidewalls 104 are used to form a Lightly Doped Drain (LDD) structure. The fourth silicon nitride film 104A with which the fin 108 is removed in the etching back.

(19) The ion injection is performed to the source/drain region 106, thereby forming the LDD structure.

(20) The stress applying layer 105 is formed on the source/drain region 106 by the selective growth.

As illustrated in FIG. 1C, because the facet is not generated in the portion F1, the stress applying layer 105 is in contact with the film 109 with no gap. As illustrated in FIG. 1B, because the facet is not generated in the portion F2, the stress applying layer 105 is in contact with the sidewall 104 with no gap. Therefore, the volume of the stress applying layer 105 becomes larger than that of the stress applying layer 505 of the comparative example, so that the larger stress can be applied to the channel region 107 sandwiched between the source/drain regions 106.

(21) The third silicon nitride film 114 on the gate electrode 103 is removed. It is not always necessary to remove the third silicon nitride film 114.

FinFET 100 of FIG. 1A is formed through the above-described processes. The following processes are similar to those of the conventional FinFET. That is, a silicide film is formed in the surfaces of the gate electrode 103 and stress applying layer 105 (source/drain region 106). Then, an inter-layer insulating film is deposited so as to bury FinFET 100. Then, a contact plug is formed in the inter-layer insulating film, and a metal interconnection is formed on the inter-layer insulating film. The metal interconnection is electrically connected to FinFET 100 through the contact plug.

In the first embodiment, the silicon nitride is cited as the material used for the film 109 with which the element isolation insulating film 102 is coated. However, the material used for the film 109 is not limited to the silicon nitride. For example, silicon carbide nitride (SiCN) may be used as the material for the film 109. Instead of the silicon nitride, the silicon oxide may be used as the material for the sidewall 104.

As described above, in the first embodiment, because the film 109 is formed on the element isolation insulating film 102, the stress applying layer 105 is in contact with the film 109 with no gap, and the stress applying layer 105 is also in contact with the sidewall 104 with no gap.

Therefore, the stress applying layer 105 can apply the larger stress to the channel region 107 to enhance the carrier mobility. As a result, because the channel resistance is decreased, the parasitic resistance of FinFET can be decreased. The higher driving current can also be obtained.

### Second Embodiment

A second embodiment of the invention will be described below. The second embodiment differs from the first embodiment in that a silicon on insulator (SOI) substrate is used.

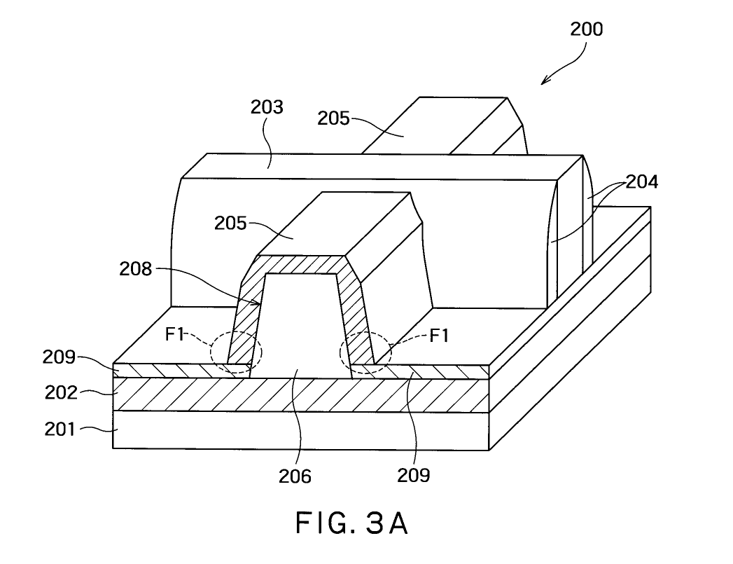

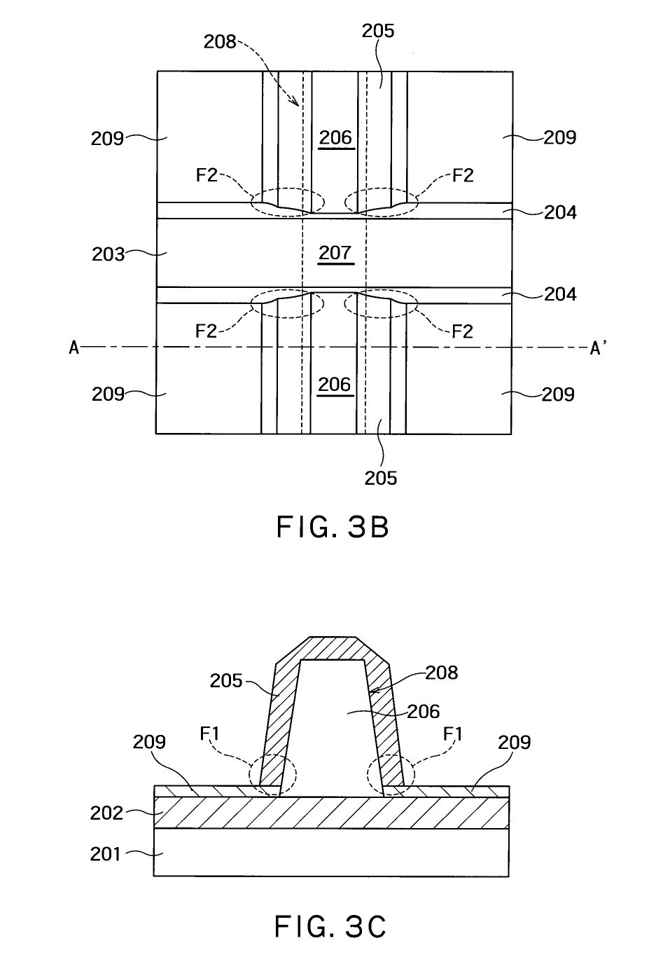

A configuration of FinFET 200 of the second embodiment will be described with reference to FIGS. 3A to 3C. FIG. 3A is a perspective view illustrating FinFET 200 of the second embodiment, FIG. 3B is a top view illustrating FinFET 200, and FIG. 3C is a sectional view taken along a line A-A′ of FIG. 3B.

Referring to FIG. 3A, FinFET 200 includes a fin 208, a gate electrode 203, sidewalls 204, a stress applying layer 205, and a gate insulating film (not illustrated). FinFET 200 is insulated from an adjacent semiconductor element by a BOX (Buried Oxide) layer 202 that is of a buried silicon oxide film.

The fin 208 is formed on the BOX layer 202. As illustrated in FIG. 3B, the fin 208 includes source/drain regions 206 and a channel region 207 that is sandwiched between the source/drain regions 206.

The gate insulating film is formed on the fin 208 of the channel region 207.

As illustrated in FIG. 3A, the gate electrode 203 is disposed so as to stride across the channel region 207. The gate electrode 203 sandwiches the channel region 207 with the gate insulating film interposed therebetween.

The sidewalls 204 are formed on both side surfaces of the gate electrode 203. For example, the sidewall 204 is made of silicon nitride (Si₃N₄).

As illustrated in FIGS. 3A to 3C, the stress applying layer 205 is formed such that, in the fin 208, an upper surface of the source/drain region 206 and both side surfaces along the channel direction are covered therewith. For example, silicon germanium (SiGe) or silicon carbide (SiC) is used as a material for the stress applying layer 205. SiGe applies the compressive stress to the channel region 207 in the gate-length direction (channel direction) to enhance the hole mobility. Therefore, SiGe is suitable to the p-type FinFET. On the other hand, SiC applies the tensile stress to the channel region 207 in the gate-length direction (channel direction) to enhance the electron mobility. Therefore, SiC is suitable to the n-type FinFET.

As illustrated in FIGS. 3A to 3C, because a film 209 made of silicon nitride is formed on the BOX layer 202, the facets are not generated in the portion F1 and the portion F2, and the stress applying layer 205 comes into contact with the film 209 and the sidewalls 204 with no gap, thereby preventing the decrease in volume of the stress applying layer 205. Because the gap is not formed between the stress applying layer 205 and the sidewall 204, the stress can efficiently be applied to the channel region 207. Therefore, the higher stress is applied to the channel region 207 to increase the carrier mobility, so that the parasitic resistance can be decreased while the driving current is increased.

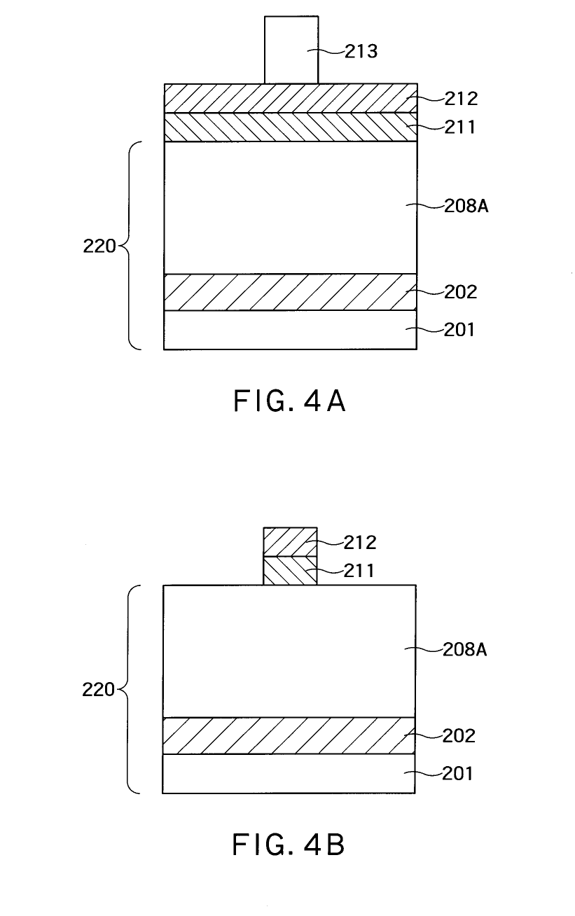

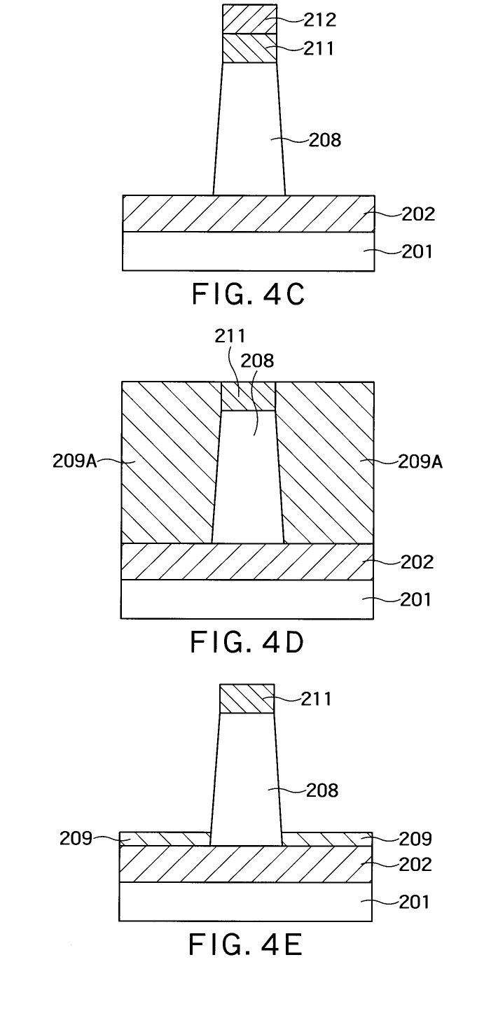

A method for producing FinFET 200 of the second embodiment will be described with reference to FIGS. 4A to 4E.

(1) Referring to FIG. 4A, a first silicon oxide (SiO₂) film 211 and a first silicon nitride (Si₃N₄) film 212 are sequentially deposited as a mask material on a SOI substrate 220. In the SOI substrate 220, the BOX layer 202 made of silicon oxide and a SOI (Silicon On Insulator) layer 208A made of single-crystal silicon are sequentially laminated on the support substrate (Si substrate) 201. Then, the photoresist is applied onto the first silicon nitride film 212 to form a photoresist film 213.

(2) As illustrated in FIG. 4A, the photoresist film 213 is patterned by the photolithography based on a shape of the fin 208.

(3) Referring to FIG. 4B, the first silicon oxide film 211 and the first silicon nitride film 212 are processed by the dry etching with the patterned photoresist film 213 as the mask.

(4) Referring to FIG. 4C, after the photoresist film 213 is removed, the SOI layer 208A is etched with the first silicon nitride film 212 as the mask until the BOX layer 202 is exposed, thereby forming the fin 208. For example, the fin 208 has a height of 100 nm to 200 nm.

(5) Referring to FIG. 4D, a second silicon nitride film 209A is deposited on the BOX layer 202, the fin 208, and the first silicon nitride film 212.

(6) As illustrated FIG. 4D, the second silicon nitride film 209A is planarized by CMP with the first silicon oxide film 211 as the stopper.

(7) Referring to FIG. 4E, the second silicon nitride film 209A is retreated to form the film 209 by the dry etching with the first silicon oxide film 211 as the mask. The BOX layer 202 is covered with the film 209. For example, the film 209 has the thickness of 10 nm.

Because the following processes are similar to those of the first embodiment, the description will not be repeated.

In the second embodiment, the silicon nitride is cited as the material used for the film 209 with which the BOX layer 202 is coated. However, the material used for the film 209 is not limited to the silicon nitride. For example, silicon carbide nitride (SiCN) may be used as the material for the film 209. Instead of the silicon nitride, the silicon oxide may be used as the material for the sidewall 204.

As described above, in the second embodiment, because the film 209 is formed on the BOX layer 202, the stress applying layer 205 is in contact with the film 209 with no gap, and the stress applying layer 205 is also in contact with the sidewall 204 with no gap.

Therefore, the stress applying layer 205 can apply the larger stress to the channel region 207 to enhance the carrier mobility. As a result, because the channel resistance is decreased, the parasitic resistance of FinFET can be decreased. The higher driving current can also be obtained.

Additional advantages and modifications will readily occur to those skilled in the art.

Therefore, the invention in its broader aspects is not limited to the specific details and representative embodiments shown and described herein.

Accordingly, various modifications may be made without departing from the spirit or scope of the general inventive concepts as defined by the appended claims and their equivalents.

1. A semiconductor device comprising:
a fin portion that includes a pair of source/drain regions located on both end sides and a channel region sandwiched between the pair of source/drain regions;
films that are formed on both sides in a channel-width direction of the fin portion;
a gate electrode that is provided so as to stride across the channel region of the fin portion;
a gate insulating film that is interposed between the gate electrode and the channel region; and
a stress applying layer that applies a stress to the channel region of the fin portion, an upper surface and side surfaces of the source/drain region in the fin portion being coated with the stress applying layer, a lower end surface of the stress applying layer being in contact with the film with no gap.

2. The semiconductor device according to claim 1, further comprising:
a silicon substrate; and
a silicon oxide film that is provided between the silicon substrate and the film,
wherein the fin portion is formed on the silicon substrate while formed integrally with the silicon substrate.

3. The semiconductor device according to claim 2, wherein the film is made of silicon nitride or silicon carbide nitride, and
the stress applying layer is made of silicon germanium or silicon carbide.

4. The semiconductor device according to claim 3, further comprising sidewalls that are formed on both side surfaces of the gate electrode, the sidewall being in contact with the stress applying layer with no gap.

5. The semiconductor device according to claim 4, wherein the sidewall is made of silicon nitride or silicon oxide.

6. The semiconductor device according to claim 2, further comprising sidewalls that are formed on both side surfaces of the gate electrode, the sidewall being in contact with the stress applying layer with no gap.

7. The semiconductor device according to claim 6, wherein the sidewall is made of silicon nitride or silicon oxide.

8. The semiconductor device according to claim 1, further comprising:
a support substrate; and
a BOX layer that is formed on the support substrate, the BOX layer being made of silicon oxide,
wherein the fin portion and the film are formed on the BOX layer.

9. The semiconductor device according to claim 8, wherein the film is made of silicon nitride or silicon carbide nitride, and
the stress applying layer is made of silicon germanium or silicon carbide.

10. The semiconductor device according to claim 9, further comprising sidewalls that are formed on both side surfaces of the gate electrode, the sidewall being in contact with the stress applying layer with no gap.

11. The semiconductor device according to claim 10, wherein the sidewall is made of silicon nitride or silicon oxide.

12. The semiconductor device according to claim 8, further comprising sidewalls that are formed on both side surfaces of the gate electrode, the sidewall being in contact with the stress applying layer with no gap.

13. The semiconductor device according to claim 12, wherein the sidewall is made of silicon nitride or silicon oxide.

14. A semiconductor device producing method comprising:
preparing a silicon substrate;
depositing sequentially a first mask material and a second mask material on the silicon substrate;
patterning the first mask material and the second mask material;
forming a substrate main body and a fin portion by etching the silicon substrate from a surface to a predetermined depth with the patterned second mask material as a mask, the fin portion being formed on the substrate main body while formed integrally with the substrate main body, the fin portion including a pair of source/drain regions located on both end sides and a channel region sandwiched between the pair of source/drain regions;
depositing silicon oxide on the substrate main body, the fin portion, and the second mask material;
forming an element isolation insulating film on the substrate main body by etching the silicon oxide film to a predetermined thickness with the second mask material as a mask;
depositing a silicon nitride film or silicon carbide nitride film on the element isolation insulating film, the fin portion, and the second mask material;
forming a film on the element isolation insulating film by etching the silicon nitride film or the silicon carbide nitride film to a predetermined thickness with the first mask material as a mask;
forming a gate insulating film on the fin portion;
forming a gate electrode that sandwiches the channel region of the fin portion, the gate insulating film being interposed between the gate electrode and the channel region; and
forming a stress applying layer such that an upper surface and both side surfaces of the source/drain region of the fin portion are coated with the stress applying layer, the stress applying layer being in contact with the film with no gap, the stress applying layer being made of silicon germanium or silicon carbide.

15. The semiconductor device producing method according to claim 14, comprising:
between the formation of the gate electrode and the formation of the stress applying layer,
depositing a sidewall insulator on the gate electrode, the source/drain region, and the film, the sidewall insulator being made of silicon nitride or silicon oxide; and
forming sidewalls on both side surfaces of the gate electrode by etching back the sidewall insulator.

16. A semiconductor device producing method comprising:
preparing a SOI substrate in which a BOX layer and a SOI layer are sequentially laminated on a support substrate;
depositing sequentially a first mask material and a second mask material on the SOI layer;
patterning the first mask material and the second mask material;
forming a fin portion by etching the SOI layer until the BOX layer is exposed with the patterned second mask material as a mask, the fin portion being formed on the BOX layer, the fin portion including a pair of source/drain regions located on both end sides and a channel region sandwiched between the pair of source/drain regions;
depositing a silicon nitride film or a silicon carbide nitride film on the BOX layer, the fin portion, and the second mask material;
forming a film on the BOX layer by etching the silicon nitride film or the silicon carbide nitride film to a predetermined thickness with the first mask material as a mask;
forming a gate insulating film on the fin portion;
forming a gate electrode that sandwiches the channel region of the fin portion, the gate insulating film being interposed between the gate electrode and the channel region; and
forming a stress applying layer such that an upper surface and both side surfaces of the source/drain region of the fin portion are coated with the stress applying layer, the stress applying layer being in contact with the film with no gap, the stress applying layer being made of silicon germanium or silicon carbide.

17. The semiconductor device producing method according to claim 16, comprising:
between the formation of the gate electrode and the formation of the stress applying layer,
depositing a sidewall insulator on the gate electrode, the source/drain region, and the film, the sidewall insulator being made of silicon nitride or silicon oxide; and
forming sidewalls on both side surfaces of the gate electrode by etching back the sidewall insulator.
